(19) United States
(12) Patent Application Publication
(10) Pub. No.: US 2006/0035423 A1
(43) Pub. Date: Feb. 16, 2006

(54) Organic electronic component comprising the same organic material for at least two functional layers

(76) Inventors: Walter Fix, Nurnberg (DE); Henning Rost, Erlangen (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 10/535,449

(22) PCT Filed: Nov. 13, 2003
(86) PCT No.: PCT/DE03/03776

§ 371 Date: May 19, 2005

(30) Foreign Application Priority Data
Nov. 19, 2002 (DE) 102 53 955.3

(51) Int. Cl. H01L 21/8234

(52) U.S. Cl. 438/197

(57) ABSTRACT

The present invention describes an organic electronic component, such as an organic field effect transistor (OFET), in which a single organic material serves for at least two functional layers, for example as conductive and as semiconductive functional material. Moreover, the invention describes an efficient method for producing, in one process step, two functional layers, for example source and drain electrodes, and the semiconductor layer, for use in organic field effect transistors. The conductive or semiconductive regions in the semiconductive or conductive matrix are obtained, for example, by doping, for example by a partial redox reaction.

The present invention describes an organic electronic component, such as an organic field effect transistor (OFET), in which a single organic material serves for at least two functional layers, for example as conductive and as semiconductive functional material. Moreover, the invention describes an efficient method for producing, in one process step, two functional layers, for example source and drain electrodes, and the semiconductor layer, for use in organic field effect transistors.

For example, PCT/DE 02/01948 discloses an organic electronic component in which the conductive layer is substantially composed of doped conjugated systems, such as doped polyacetylene or polyaniline, and the semiconductive layer is substantially composed of conjugated systems, such as polythiophene or polythienylvinylene (PTV). In the case of the known organic electronic components, the semiconductive functional layer is as a rule always produced from different organic material to the conductive functional layer, so that, at least for semiconductive and conductive functional layer, two different functional layers always lie one on top of the other and are produced in two process steps.

In the production of organic electronic components, such as, for example, OFETs in top gate configuration, a conductive functional layer comprising a conjugated polymer (e.g. polyaniline, PEDOT/PSS, etc.) has to date been applied to a substrate comprising glass or plastic by either printing, knifecoating or spincoating. In the latter two methods, a structuring process optionally also follows, by means of which the source and drain electrodes are produced, which electrodes can be produced directly in the case of printing. In a further process step, an organic semiconductor layer comprising another conjugated polymer is applied to this functional layer, it being necessary to ensure that neither the solvent used for the semiconductor material nor the semiconductor material itself attacks (i.e. partially dissolves, delaminates or dissolves) the polymer electrodes underneath. It should furthermore be ensured that electrodes and semiconductor “match one another well”, i.e. are tailored to one another both with respect to mechanical adhesion and with respect to good agreement of work function and HOMO value. This method is complicated and expensive, and there is therefore a need to improve this method, in particular to save process steps in the production.

It is an object of the invention to provide an organic electronic component in which a single organic material can be used for the production of at least two functional layers, for example the conductive and the semiconductive functional layers, both functional layers, i.e. the lower structured conductive functional layer and the adjoining semiconductive functional layer, being applied together in one process step, effectively as one functional layer.

The invention relates to an electronic organic component comprising at least two functional layers adjacent to one another, the first functional layer being produced from the same organic material as the second and adjacent functional layer but differing at least partly therefrom in its electrical physical properties (such as, for example, the conductivity). Moreover, the invention relates to a method for the production of an organic electronic component, in which two different functional layers are produced in a single process step by converting a part of the functional layer into another modification of the material by partial reaction.

“Partial reaction” means that a part of the functional layer is modified in its physical properties, such as conductivity, by external action (redox composition, radiation, other chemicals, mechanical treatment, physical treatment, introduction of extraneous atoms, doping).

“Other modification” of the same organic material refers to the physical changing of a substance into another state, for example solid-liquid or conductive-nonconductive. There is no fundamental change in the chemical composition of the material, apart from small changes due to introduction of extraneous atoms, etc. For example, the redox potential of the organic material is changed.

One embodiment comprises a method for the production of an organic electronic component, in which, in a single process step, electrodes and/or conductor tracks and semiconductive functional layer are produced with structuring in a single organic material.

According to one embodiment of the method, a conductive structure is introduced in a controlled manner into the semiconductive functional layer by partial covering and subsequent treatment of the uncovered regions with a redox composition.

According to one embodiment, the semiconductive layer is partly covered by means of a photoresist, so that the uncovered regions can be used for producing electrodes and/or conductor tracks by bringing into contact with a redox composition.

According to one embodiment, a redox composition is partially applied to the semiconductor functional layer by printing.

According to one embodiment, partial oxidation of the semiconductor functional layer is carried out by means of an oxidizing agent.

Organic material refers here, inter alia, to a material which can be modified completely or partly and/or in certain regions in its electrical properties, such as the conductivity, by controlled reduction or oxidation. The controlled oxidation/reduction is effected chemically and/or electrochemically, i.e. galvanically, and can, for example, also be effected after the application and structuring of a photoresist with subsequent chemical and/or electrochemical/electrical treatment of the exposed regions.

Here, the term “organic material” and/or “functional polymer” includes all types of organic, organometallic and/or inorganic plastics, which are referred to in English, for example, as “plastics”. These are all types of substances with the exception of the semiconductors, which form the classical diodes (germanium, silicon), and the typical metallic conductors. A restriction in the dogmatic sense to organic material as carbon-containing material is accordingly not envisaged; rather, the broad use of, for example, silicones is also intended. Furthermore, the term is not intended to be subject to any restriction with respect to the molecular size, in particular to polymeric and/or oligomeric materials, and instead the use of small molecules is also entirely possible.

For example, conjugated polymers, such as poly(phenylenevinylene) (PPV), specific polyfluorenes (PF) or polyalkylthiophenes PAT, are described as semiconductor material for use in organic electronic components, such as OFETs. It is known that such special polymers can be converted into the conductive state by so-called doping, i.e. by a redox reaction with a redox composition, such as oxidation with oxidizing agents such as (iodine (I₂), bromine (Br₂), iron(III) chloride (FeCl₃), nitrosyl tetrafluoroborate (NOBF₄) and potassium peroxodisulfate (K₂S₂O₈), etc.). If a homogeneous layer of an organic functional material which is to be used as semiconductor material is now produced on a suitable substrate material (glass, plastic) by printing, knifecoating, spincoating, spray application, etc., it is possible, by use of a screening material, for example of a photoresist (i.e. photolithography), or printing on of an etch resist, to cover certain regions of the semiconductive functional layer so that the uncovered regions of the semiconductive functional layer can be converted into the conductive form by bringing into contact with redox compositions. Another possibility consists in printing the redox composition directly onto the semiconductor.

Thus, for example, an electrode and/or a conductor track comprising the oxidized form of the semiconductive material can be produced in an unconductive matrix of the same semiconductive material.

Below, the invention is to be explained in more detail with reference to a working example:

A homogeneous layer of the semiconductive polymer poly(3,3″-dihexyl-2,2′-5,2″-terthiophene) PDHTT is applied to a PET substrate by spincoating. A functional layer of a positive photoresist (e.g. AZ 1512 from Clariant) is applied thereon by spincoating. By means of a shadow mask, the photoresist is exposed to UV light and then developed. In this way, defined regions in which PHDTT is no longer protected by the photoresist form When the substrate is immersed in a 0.1 molar solution of iron(III) chloride hydrate in acetonitrile, the exposed regions are oxidized to the conductive form. The oxidizing agent is then washed away with solvent, drying is effected, and the photoresist remaining on the substrate is removed. In this way, conductive structures are obtained in a nonconductive matrix.

The conductive or semiconductive regions in the semiconductive or conductive matrix are also obtained by doping, for example by a partial redox reaction.

Regarding the electrical properties of an organic electronic component, such as an OFET, there are the following two substantial advantages as a result of the uniformity of the conductive and semiconductive functional layer:

Firstly, the contact resistance between electrode and semiconductor is substantially reduced (usually, contact resistances form at interfaces between two different organic functional materials due to space charge zones as a result of different Fermi levels and/or due to potential barriers as a result of weak bonds of the organic functional materials with one another).

Furthermore, the series resistance which forms in the case of organic electronic components, such as OFETs, is avoided by virtue of the fact that the semiconductor layer is present between source/drain electrode and insulator, but the current channel forms only at the semiconductor/insulator interface. The current channel thus has no direct contact with the source/drain electrode. In the case of organic electronic components, such as OFETs, which are made according to the invention with uniform organic functional material for semiconductive and conductive functional layer, the current channel is in direct contact with the source/drain electrodes.

As a consequence of the described design of an electronic organic component, such as an OFET, switching operations can be realized more rapidly and moreover require lower supply voltages.

Finally, the invention has a considerable advantage in production because two functional layers of an electronic organic component can be produced by only a single process step. Thus, for example, electrode/conductor tracks and semiconductors are produced with structuring in one layer. Moreover, mechanical adhesion problems, which usually have to be overcome by using different materials for source/drain electrodes and/or conductor tracks and semiconductors, are avoided.

1. An electronic organic component comprising at least two functional layers adjacent to one another, the first functional layer being produced from the same organic material as the second and adjacent functional layer but differing at least partly therefrom in its electrical physical properties.

2. The electronic organic component as claimed in claim 1, in which one of the functional layers is semiconductive, the semiconductive functional Layer and at least one other functional layer differ only in their redox potential.

3. A method for the production of an organic electronic component, in which two different functional layers are produced in a single process step by converting a part of a functional layer into another functional layer by modification of the material by partial reaction.

4. The method as claimed in claim 3, in which electrodes and/or conductor tracks and a semiconductive functional layer are produced with structuring in one process step and in one functional layer.

5. The method as claimed in claim 3 wherein one of the functional layers is a semiconductive layer, in which a conductive structure is introduced in a controlled manner into the semiconductive functional layer by partial covering and treatment of the uncovered regions with a redox composition.

6. The method as claimed in claim 3, in which one of the functional layers is a semiconductive layer and the semiconductive layer is covered by a photoresist.

7. The method as claimed in claim 5, in which the redox composition is partially applied to the semiconductive functional layer by printing.

8. The method as claimed in claim 3, in which a time-stable partial oxidation of the semiconductive functional layer is carried out by an oxidizing agent.

9. The method as claimed in claim 4, in which a conductive structure is introduced in a controlled manner into the semiconductive functional layer by partial covering and treatment of the uncovered regions with a redox composition.

10. The method as claimed in claim 4 in which the semiconductive layer is covered by a photoresist.

11. The method as claimed in claim 5 in which the semiconductive layer is covered by a photoresist.

12. The method as claimed in claim 3 wherein one of the functional layers is a semiconductive functional layer in which a redox composition is partially applied to the semiconductive functional layer by printing.

13. The method as claimed in claim 4 in which a redox composition is partially applied to the semiconductive functional layer by printing.

14. The method as claimed in claim 6 in which a redox composition is partially applied to the semiconductive functional layer by printing.

15. The method as claimed in claim 4 in which a time-stable partial oxidation of the semiconductive functional layer is carried out by an oxidizing agent.

16. The method as claimed in claim 5 in which a time-stable partial oxidation of the semiconductive functional layer is carried out by an oxidizing agent.

17. The method as claimed in claim 6 in which a time-stable partial oxidation of the semiconductive functional layer is carried out by an oxidizing agent.

18. The method as claimed in claim 7 in which a time-stable partial oxidation of the semiconductive functional layer is carried out by an oxidizing agent.
